(19) United States
(12) Patent Application Publication
(10) Pub. No.: US 2006/0220179 A1
(43) Pub. Date: Oct. 5, 2006

(54) Method for forming an improved isolation junction in high voltage LDMOS structures

(75) Inventors: You-Kuo Wu, Shijhih City (TW); Edward Chiang, Hsinchu City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 11/097,744

(22) Filed: Apr. 1, 2005

(51) Int. Cl. H01L 29/00

(52) U.S. Cl. 257/544; 257/E29.029

(57) ABSTRACT

A method for forming an improved isolation junction in an LDMOS structure to reduce current leakage at high operating Voltages including forming doped regions in a buried layer prior to forming an overlying epitaxial region including doped isolation regions followed by a drive-in process to form a continuous isolation region by intermixing the doped regions formed in the buried layer with the overlying doped isolation regions.

### FIELD OF THE INVENTION

This invention generally relates to microelectronic integrated circuit (IC) semiconductor device fabrication and more particularly to a method for integrated manufacturing of high Voltage integrated circuits (HVIC) including improved isolation junctions in laterally diffused MOS (LDMOS) devices.

### BACKGROUND OF THE INVENTION

With increasing demands for high power integrated circuits, the formation of high power devices such as amplifiers has required higher operating Voltages with corresponding required higher breakdown Voltages of the gate oxide in CMOS devices. This requirement has been accomplished by lateral diffusion MOS devices. The formation of LDMOS structures basically involves lateral diffusion of dopants on the source side to below the gate region as well as lateral diffusion from under the gate region toward the drain region to achieve reduced ON resistance and higher breakdown Voltage.

Prior art processes have proposed the formation of buried layer formation in a silicon substrate to prevent Voltage punch through at relatively high operating Voltages, for example greater than about 25 Volts. In addition, to prevent current leakage, for example between source regions and bulk regions, especially where a Voltage bias is applied during operation, for example a CMOS amplifier, N-type LDMOS isolation regions adjacent high Voltage P-well and N-well regions are typically formed.

As operating Voltages have increased, the tendency has been to increase the thickness of epitaxially deposited silicon (epi Si layers) formed over the silicon substrate for formation of P-well, N-well, and isolation regions. For example, the dielectric breakdown strength is increased by relatively thicker epi Si layers, allowing operation at higher Voltages. One problem in prior art LDMOS structures, is the tendency for the current leakage problem to be exacerbated as the epi Si layer thicknesses and operating Voltages are increased.

Thus, there is a need in the semiconductor manufacturing art for improved method for manufacturing LDMOS structures to increase junction isolation to reduce current leakage in order to allow the formation of LDMOS devices operating at higher Voltages with improved device performance and reliability.

It is therefore an object of the invention to provide an improved method for manufacturing LDMOS structures to increase junction isolation to reduce current leakage in order to allow the formation of LDMOS devices operating at higher Voltages with improved device performance and reliability, while overcoming other shortcomings and deficiencies of the prior art.

### SUMMARY OF THE INVENTION

To achieve the foregoing and other objects, and in accordance with the purposes of the present invention, as embodied and broadly described herein, the present invention provides an improved isolation junction in an LDMOS structure and method for forming the same to reduce current leakage at high operating Voltages

In a first embodiment, the method includes forming doped regions in a buried layer prior to forming an overlying epitaxial region including doped isolation regions followed by a drive-in process to form a continuous isolation region by intermixing the doped regions formed in the buried layer with the overlying doped isolation regions.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1F are cross sectional side views of a portion of an exemplary high Voltage N-type LDMOS structure stages of manufacture according to an embodiment of the present invention.

FIG. 2 is a process flow diagram including several embodiments of the present invention.

### DETAILED DESCRIPTION OF THE PREFERRED EMBODIMENTS

Although the method of the present invention is particularly applicable to the formation of a laterally diffused (LD) NMOS device, it will be appreciated that the inventive concept may be applied to PMOS LDMOS devices as well. In addition, although an exemplary LDMOS device is shown in implementing the method of the present invention, other exemplary LDMOS devices, for example as shown in co-assigned U.S. Pat. No. 6,475,870 which is hereby incorporated by reference in its entirety, may be advantageously formed according to embodiments of the present invention.

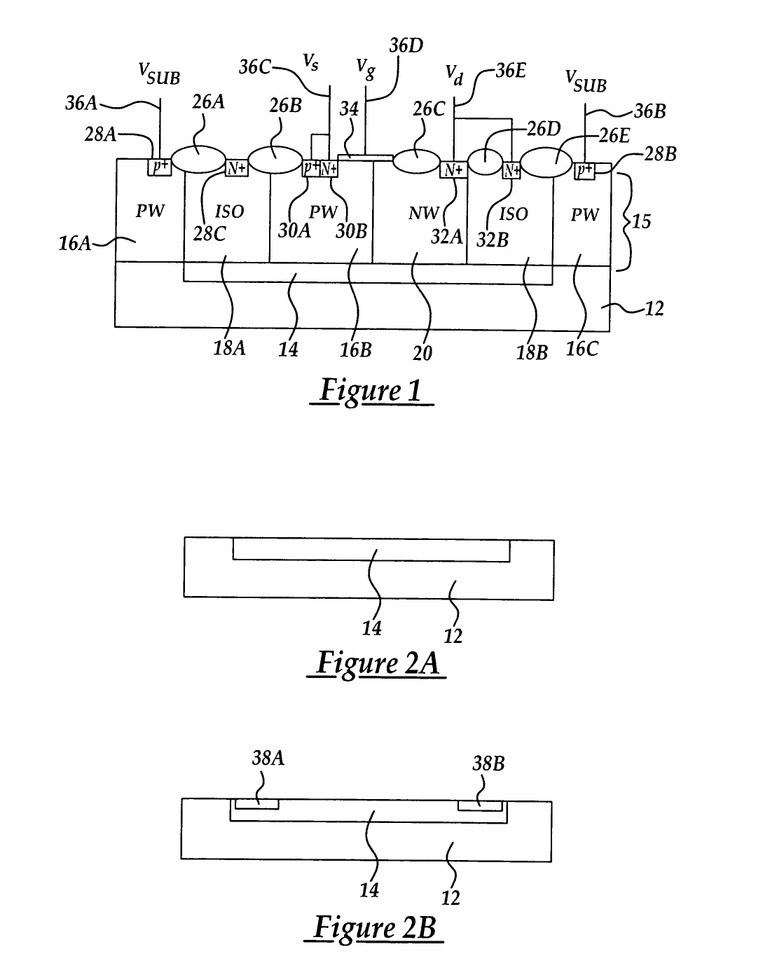

For example referring to FIG. 1 is an exemplary portion of high Voltage N-type LDMOS (LDNMOS) device formed according to an embodiment of the present invention. Shown is a conventional P-doped silicon substrate 12 having an overlying N-doped buried layer (NBL) region 14 formed by conventional methods followed by deposition of an epitaxially grown silicon layer 15 for formation of various doped regions. For example, following formation of the EPI layer, ion implantations are carried out to form high Voltage P-well (PW) regions 16A, 16B, and 16C, isolation regions (ISO) 18A and 18B, and high Voltage N-well (NW) region 20. In accordance with an embodiment of the method of the present invention, the isolation regions e.g., 16A and 16B are formed to fully extend through (penetrate) the thickness of the epitaxial silicon layer to make contact with the of the NBL region 14.

Subsequent conventional processes are carried out to complete the formation of the exemplary LDMOS device including formation of LOCOS isolation regions 26A, 26B, 26C, 26D, and 26E as well as doped P-well contact regions 28A (P+), 28B (P+), and 28C(N+), doped P-well source contact regions 30A (P+) and 30B (N+), and drain regions 32A (N+) and 32B (N+). In addition, gate structure 34, and appropriate metal interconnects, for example damascene contacts are formed for forming electrical circuit connections shown as Voltage supply V_{sub}, 36A, 36B, Vₛ (source) 36C, Vg (gate) 36D, and V_{d} (drain) 36E.

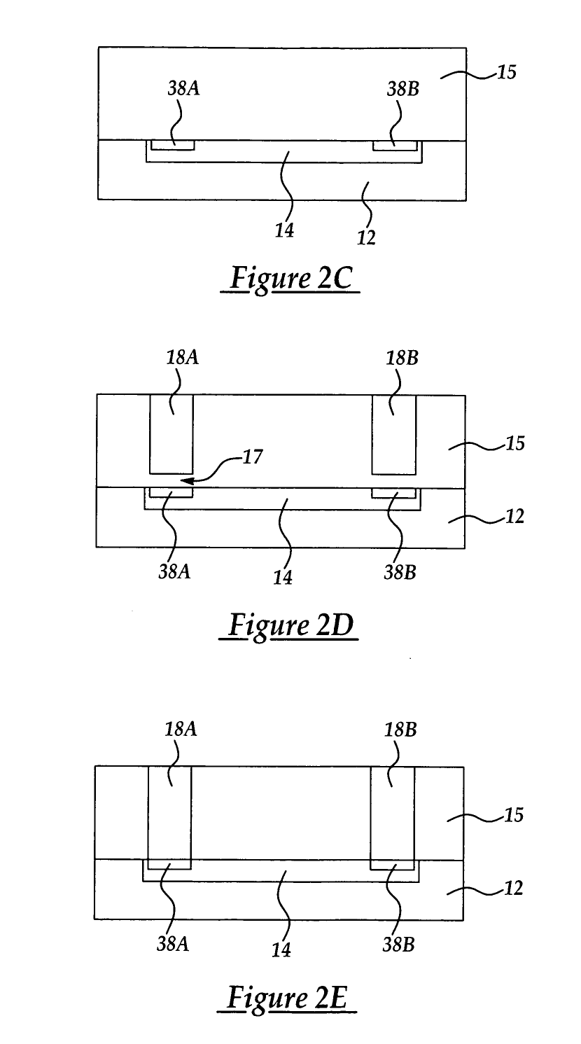

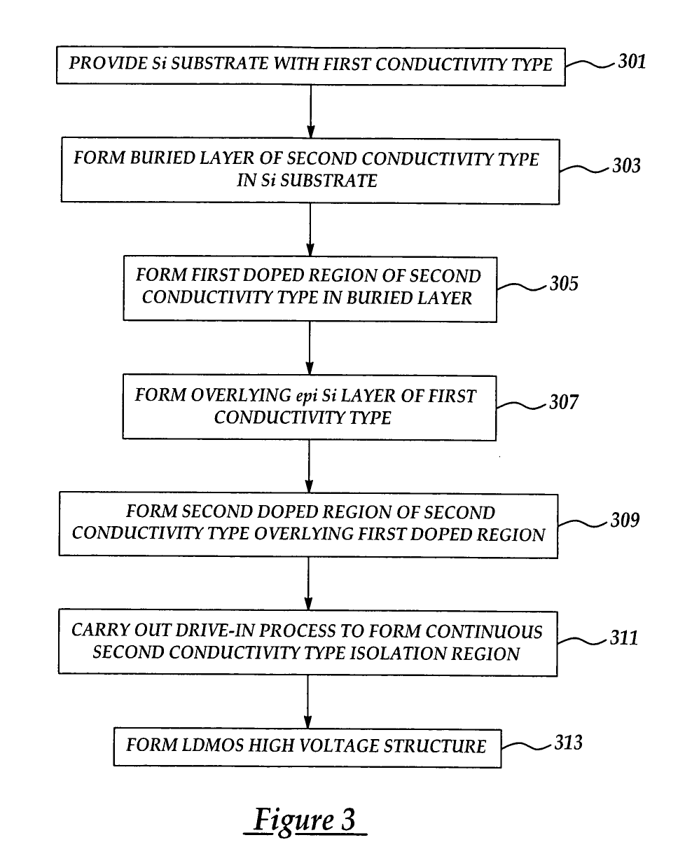

Referring to FIG. 2A, a doped silicon substrate 12, for example P-doped is provided. A first sacrificial oxide layer (not shown) is then formed, e.g., thermally grown (thermal oxide) to an appropriate thickness (e.g., 150 Angstroms) to modulate a desired ion implant followed by a conventional photolithographic patterning process to form an ion implant mask. A conventional ion implantation process is carried out to form an N-type buried layer (NBL) region 14. For example the NBL region is formed by an ion implant with appropriate energy to form a layer having a thickness extending between about 0.5 and 3 microns from the silicon substrate surface following a thermally activated diffusion (drive-in) treatment. It will be appreciated that conventional N-type dopants such as arsenic, antimony, or phosphorus may be used, for example using ion energies of between about 80 and 120 keV for a total dosage between about 10¹⁴ and 10¹⁵ ions per cm³.

Following the NBL implant, the photoresist implant mask (not shown) is removed and the substrate cleaned followed by a drive-in diffusion carried out by conventional means, for example, a conventional thermal treatment at a temperature of from about 900° C. to about 1300° C.

Referring to FIG. 2B, according to an aspect of the present invention, the first sacrificial oxide layer (not shown) formed to modulate the NBL implant is removed, for example by a conventional wet etch process, followed by formation of a second sacrificial oxide layer (thermal oxide) (not shown) of an appropriate thickness to carry out a shallow N-type dopant ion implant to form shallow N-type regions, e.g., 38A and 38B within the NBL over which subsequent N-type isolation (iso) regions will be formed. Although not shown it will be appreciated that an ion implant mask is formed by conventional lithographic methods to define the implant area to form the shallow N-type implant regions, e.g., 38A and 38B, also referred to herein as bottom-iso regions, followed by an ion implantation process. The doping process is preferably carried out to produce a concentration (dosage) of the N-type dopant ions in the bottom-iso regions of up to about 5×10¹³ N dopant ions/cm³.

Referring to FIG. 2C, following formation of the bottom-iso regions 38A, 38B, and removal of the implant mask (not shown), and the second sacrificial oxide layer (not shown), a P-type epitaxial silicon layer (epi layer) 15 is formed by conventional means to a thickness from about 4 microns to about 15 microns, more preferably greater than about 4.5 microns, for example about 10 microns.

Referring to FIG. 2D, following formation of the EPI layer 15, a third sacrificial oxide layer may optionally be formed over the epi layer 15. Conventional photolithographic processes are carried out to form an ion implant mask (not shown) to form N-type ion implanted regions, referred to as isolation regions, e.g. 18A and 18B, in the epi layer 15 overlying the bottom iso-regions 38A and 38B. The isolation regions e.g., 18A and 18B are formed by using conventional N-type dopants and carrying out a high-energy ion implantation, for example from about 200 keV to 1000 keV. Following the ion implant process, an epi layer P-type conductivity thickness portion of layer 15, e.g., 17 will frequently remain underlying the deepest portion of the N-type implant, for example where the epi layer 15 is greater than about 4.5 microns.

Referring to FIG. 2E, following the ion implant process to form the isolation regions 38A and 38B, a thermal drive-in treatment including one or more thermal treatments at temperatures from about 1000° C. to about 1350° C. are carried out such that the bottom-iso regions 38A and 38B and the isolation regions 18A and 18B, respectively diffuse to touch one-another, eliminating the P-type epi layer regions, e.g., 17, and forming a continuous N-doped isolation region extending through the thickness (penetrating) the epi layer 15.

For example, it has been found that carrying out conventional high-energy N-type ion implants in the epi layer 15 to form a deep N-type implant isolation regions, that following one or more annealing treatments (thermal drive-in process), a primarily P type epi layer gap remains between the NBL layer and the N-doped isolation regions. This has been found to occur when the epi layer e.g., 15, is formed at greater than about 4.5 microns, particularly greater than about 7.0 microns. When the LDMOS devices is operating at applied Voltages e.g., V_{d} and Vₛ at about 100 Volts and 90 Volts respectively, the epi layer P-type region (gap) remaining between the NBL layer and isolation region can contribute to leakage currents as high as 40 micro-Amps for a 9 micron thick epi layer.

By forming the bottom iso-regions, e.g., 38A and 38B according to preferred embodiments, a drive-in thermal treatment following the isolation implant results in an isolation region continuous with the NBL layer thereby forming a continuous N-doped isolation region with significantly lower leakage current. For example, by providing an N-type dopant, in the bottom-iso regions e.g., 38A and 38B formed according to preferred embodiments, a leakage current in an N-type LDMOS device (see e.g., FIG. 1) using a 9 micron thick epi layer is reduced from about 40 micro-Amps to less than about 10 nano-Amps at a source Voltage of about 100 Volts.

Conventional processes are then carried out as are known in the art to complete the formation of the LDMOS device as shown in FIG. 1. For example, deep N-well and P-well ion implants are carried out followed by formation of LOCOS regions. Gate structures are then formed followed by and subsequent ion implantations to form source, drain, and bias Voltage contact regions.

Referring to FIG. 3 is shown a process flow diagram including several embodiments of the present invention. In process 301 a silicon substrate having a first type conductivity (e.g., one of N and P) is provided. In process 303 a buried layer region of a second type conductivity is formed in a surface portion of the substrate. In process 305, a first doped region of the second type conductivity having an increased second conductivity dopant ion density (concentration) is provided within the buried layer. If process 307, an epitaxially silicon layer (epi Si layer) of the first type conductivity is formed over and contacting the buried layer. In process 309, a second doped region of the second type conductivity is formed in the epi Si layer overlying the first doped region. In process 311, one or more annealing steps are carried out to form a continuous doped region from the first and second doped region to form an isolation region. In process 313, conventional processes are carried out to form an LDMOS device.

The preferred embodiments, aspects, and features of the invention having been described, it will be apparent to those skilled in the art that numerous variations, modifications, and substitutions may be made without departing from the spirit of the invention as disclosed and further claimed below.

1. A method for forming an improved isolation junction in an LDMOS structure comprising the steps of:
providing a semiconductor substrate comprising a first conductivity;
forming a first doped region comprising a second conductivity extending a first thickness from the semiconductor substrate surface;
forming a second doped region comprising the second conductivity within the first doped region at a higher doping density compared to the first doped region;
forming an epitaxial semiconductor layer comprising a first conductivity over and contacting the first and second doped regions;
forming a third doped region comprising the second conductivity within the epitaxial semiconductor layer overlying the second doped region extending a second thickness from the epitaxial semiconductor layer surface; and,
carrying out at least one thermal treatment to intermix the second and third doped regions.

2. The method of claim 1, wherein the first and second conductivity are selected from the group consisting of P and N conductivity.

3. The method of claim 1, wherein the second conductivity consists essentially of N conductivity and the first conductivity consists essentially of P conductivity.

4. The method of claim 1, wherein the first doped region comprises an N conductivity buried layer (NBL) and the first thickness is from about 0.5 microns to about 3 microns.

5. The method of claim 1, wherein the second and third doped regions are formed by an ion implantation process comprising N conductivity dopants selected from the group consisting of arsenic, phosphorous, and antimony.

6. The method of claim 1, wherein at a thermal drive-in treatment is avoided following the step of forming a second doped region prior to the step of formation of the epitaxial semiconductor layer.

7. The method of claim 1, wherein the epitaxial semiconductor layer is formed at a thickness greater than about 4.5 microns.

8. The method of claim 1, wherein the second thickness does not extend to make contact with the first doped region.

9. The method of claim 1, wherein the higher doping density comprises a concentration of from about 5×10¹² to about 5×10¹³ dopant atoms per cubic centimeter.

10. The method of claim 1, wherein the third doped region comprises an isolation region in a high Voltage laterally diffused NMOS (LONMOS) device.

11. The method of claim 10, further comprising steps to complete the formation of an LDNMOS device wherein the isolation region comprises Isolation regions formed adjacent to respective P-well and N-well doped channel regions underlying a gate structure.

12. The method of claim 11, wherein the LDNMOS device is designed to operate at Voltages greater than about 75 Volts.

13. A method for forming an improved isolation junction in an LDNMOS structure comprising the steps of:
providing a semiconductor substrate comprising P-type conductivity;
forming a first doped region comprising N-type conductivity extending a first thickness from a portion of the semiconductor substrate surface;
forming a second doped region comprising N-type conductivity within a portion of the first doped region at a thickness less than the first thickness and at a higher doping density compared to the first doped region;
forming an epitaxial semiconductor layer comprising P-type conductivity type over and contacting the first and second doped regions:
forming a third doped region comprising N-type conductivity within the epitaxial semiconductor layer overlying the second doped region to extend through a portion of the epitaxial semiconductor layer surface to leave a P-type conductivity portion of the epitaxial semiconductor layer overlying the second doped region; and,
carrying out at least one annealing process to intermix the second and third doped regions to form a continuous N-type conductivity isolation region penetrating the epitaxial semiconductor layer.

14. The method of claim 13, wherein the first doped region is from about 0.5 microns to about 3 microns.

15. The method of claim 13, wherein the second and third doped regions are formed by an ion implantation process comprising N-type conductivity dopants selected from the group consisting of arsenic, phosphorous, and antimony.

16. The method of claim 13, wherein an annealing treatment is not carried out following the step of forming a second doped region prior to the step of formation of the epitaxial semiconductor layer.

17. The method of claim 13, wherein the epitaxial semiconductor layer is formed at a thickness greater than about 4.5 microns.

18. The method of claim 13, wherein the higher doping density comprises a concentration of from about 5×10¹² to about 5×10¹³ dopant atoms per cubic centimeter.

19. The method of claim 13, further comprising steps to complete formation of an LDNMOS device.

20. The method of claim 20, wherein the third doped region comprises isolation regions in a high voltage laterally diffused NMOS (LDNMOS) device formed adjacent to respective P-well and N-well doped channel regions underlying a gate structure.

21. An LDMOS structure having an improved isolation junction comprising:
a semiconductor substrate comprising a first conductivity type;
a first doped region comprising a second conductivity type extending a first thickness from the semiconductor substrate surface;
a second doped region comprising the second conductivity type within the first doped region comprising the second conductivity type within the first doped region at a higher doping density compared to the first doped region;
a epitaxial semiconductor layer comprising a first conductivity type over and contacting the first and second doped regions;
a third doped region comprising the second conductivity type within the epitaxial semiconductor layer overlying the second doped region extending a second thickness from the epitaxial semiconductor layer surface;
wherein the second and third doped regions form a continuous doped region comprising the second conductivity type extending through the epitaxial semiconductor layer thickness.

22. The LDMOS structure of claim 21, wherein the first and second conductivity types are selected from the group consisting of P and N type conductivity.

23. The LDMOS structure of claim 21, wherein the second conductivity type consists essentially of N type conductivity and the first conductivity type consists essentially of P type conductivity.

24. The LDMOS structure of claim 21, wherein the first doped region comprises an N type conductivity buried layer (NBL) and the first thickness is from about 0.5 microns to about 3 microns.

25. The LDMOS structure of claim 21, wherein the second and third doped regions comprise N type conductivity dopants selected from the group consisting of arsenic, phosphorous, and antimony.

26. The LDMOS structure of claim 21, wherein the epitaxial semiconductor layer has a thickness greater than about 4.5 microns.

27. The LDMOS structure of claim 21, wherein the second thickness does not extend to make contact with the first doped region.

28. The LDMOS structure of claim 21, wherein the higher doping density comprises a concentration of from about 6×10¹² to about 5×10¹³ dopant atoms per cubic centimeter.

29. The LDMOS structure of claim 21, wherein the third doped region comprises an isolation region In a high voltage laterally diffused NMOS (LDNMOS) device.

30. The LDMOS structure of claim 29, wherein the isolation region is disposed adjacent to respective P-well and N-well doped channel regions underlying a gate structure.

31. The LDMOS structure of claim 29, wherein the LDNMOS device operates at voltages greater than about 75 volts.

32. An LDMOS structure having an improved isolation junction comprising:
a semiconductor substrate comprising P-type conductivity;
a first doped region comprising N-type conductivity extending a first thickness from a portion of the semiconductor substrate surface;
a second doped region comprising N-type conductivity within a portion of the first doped region at a thickness less than the first thickness and at a higher doping density compared to the first doped region;
an epitaxial semiconductor layer comprising P-type conductivity over and contacting the first and second doped regions;
wherein a third doped region comprising N-type conductivity is disposed within the epitaxial semiconductor layer overlying the second doped region to extend through a portion of the epitaxial semiconductor layer surface to form a continuous N-type conductivity isolation region penetrating the epitaxial semiconductor layer.
